(19) United States
(12) Patent Application Publication
(10) Pub. No.: US 2009/0104353 A1
(43) Pub. Date: Apr. 23, 2009

(54) Apparatus For Treating A Gas Stream

(76) Inventors: Christopher John Shaw, Sussex (GB); Christopher Mark Bailey, West Sussex (GB)

Correspondence Address: Edwards Vacuum, Inc., 55 MADISON AVENUE, Suite 400, MORRISTOWN, NJ, 07960, US

(21) Appl. No.: 12/225,085

(22) PCT Filed: Feb. 22, 2007
(86) PCT No.: PCT/GB2007/050079

§ 371 Date: Sep. 12, 2008

(30) Foreign Application Priority Data
Mar. 14, 2006 (GB) 0605048.8

(51) Int. Cl. C23C 16/54; C23C 16/44

(52) U.S. Cl. 427/255.28; 118/723 VE

(57) ABSTRACT

In a method of inhibiting the deposition of aluminium within a vacuum pump during the pumping from a process chamber of a gas stream containing an organoaluminium precursor, chlorine is supplied to the gas stream upstream of the vacuum pump to react with the precursor to form aluminium chloride, which can pass harmlessly through the pump in its vapour phase.

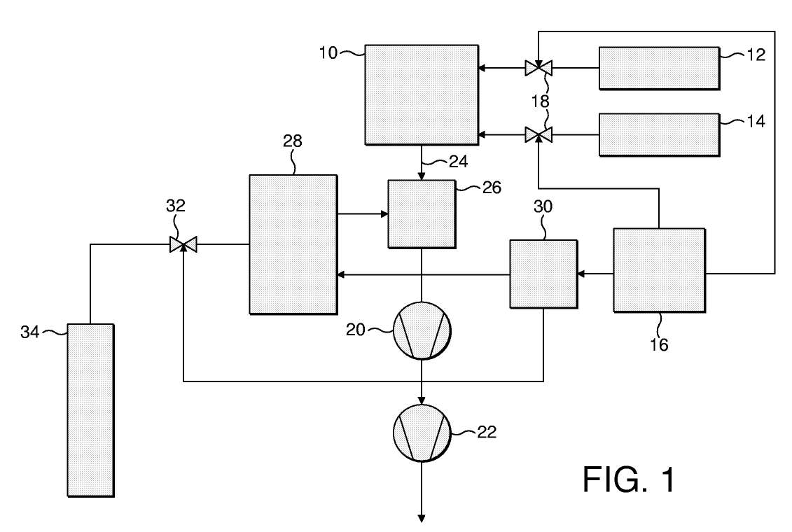

The present invention relates to apparatus for, and a method of, treating a gas stream to inhibit the deposition of aluminium or other metal within a vacuum pump during the pumping from a process chamber of a gas stream containing an organometallic precursor.

A primary step in the fabrication of semiconductor devices is the formation of a thin film on a semiconductor substrate by chemical reaction of vapour precursors. One known technique for depositing a thin film on a substrate is chemical vapour deposition (CVD). In this technique, process gases are supplied to a process chamber housing the substrate and react to form a thin film over the surface of the substrate.

A CVD process used to deposit an aluminium layer on a substrate is MOCVD (metal organic chemical vapour deposition), in which an organoaluminium precursor is supplied to the process chamber from a bubbler, the precursor being entrained within a carrier gas, such as nitrogen or argon, conveyed to the bubbler. A hydrogen reducing gas is also supplied to the process chamber for reducing the precursor. The process chamber is evacuated, and heated to a deposition temperature, generally less than 500°, at which the precursor decomposes and aluminium is deposited on to the substrate.

In such deposition processes, the residence time of the deposition gases in the processing chamber is relatively short, and only a small proportion of the gas supplied to the chamber is consumed during the deposition process. Consequently, much of the deposition gas supplied to the process chamber is exhausted from the chamber together with by-products from the deposition process, and conveyed by a foreline to a vacuum pump used to evacuate the process chamber.

During use of the vacuum pump, heat is generated as a result of the compression of the gas by the pumping mechanism of the vacuum pump. Consequently, the temperature of the pumping mechanism rapidly rises. If the temperature of the pumping mechanism is above that at which the organoaluminium precursor contained within the gas stream decomposes to form aluminium, this can result in undesirable deposition of aluminium within the pump, which can lead to damage of the pumping mechanism. The pumping of organoaluminium precursors such as dimethyl ethyl amine alane (DMEAA) and alkyl pyrroridine alanes, for example methyl pyrroridine alane (MPA), having deposition temperatures below 250° C. is particularly susceptible to aluminium deposition within the pump.

In view of this, it is common practice to use one or more heated traps upstream from the pump to remove the precursor from the gas stream before it enters the pump. These traps require frequently servicing for emptying and cleaning purposes, typically every few days, and this can incur costly downtime of the process tool. Another alternative is to heat the pump using an external heater to a temperature above that at which the precursor decomposes within the pump. However, such heaters tend to be expensive.

It is an aim of at least the preferred embodiment of the present invention to seek to solve these and other problems.

The present invention provides a method of inhibiting the deposition of aluminium within a vacuum pump during the pumping from a process chamber of a gas stream containing an organoaluminium precursor, the method comprising the step of supplying a halogen to the gas stream upstream of the vacuum pump to react with the precursor to form a gaseous aluminium halide.

The halogen is preferably chlorine, although the halogen may alternatively comprise one of bromine and iodine. By converting the precursor to, for example, aluminium chloride which can pass harmlessly through the pump in its vapour phase, the operating life of the pump can be significantly increased without the need to perform servicing of any traps located upstream from the pump. Chlorine is preferably added to the gas stream in the form of chlorine radicals. The chlorine radicals are preferably formed by the thermal decomposition of a source of chlorine radicals, for example by a plasma generator. The plasma generator may be located at any convenient location between the process chamber and the pump. CCl₄ may provide the source of chlorine radicals.

Chlorine may be conveyed into the foreline extending between the process chamber and the pump, or, more preferably, into a reaction chamber located between the process chamber and the pump.

The organoaluminium precursor may comprise one of trimethyl aluminium, triethyl aluminium, diethyl aluminium ethoxide, dimethyl aluminium hydride, triisobutyl aluminium, dimethyl ethyl amine alane, dimethyl aluminium isopropoxide, aluminium sec-butoxide, tris(dimethylamido) aluminium, tris(diethylamido) aluminium, tris(ethylmethylamido) aluminium, and an alkyl pyrroridine alane, such as methylpyrroridine alane.

The present invention also provides apparatus for treating a gas stream containing an organoaluminium precursor prior to entering a vacuum pump, the apparatus comprising means for supplying a halogen to the gas stream upstream of the vacuum pump to react with the precursor to form a gaseous aluminium halide.

The invention finds wider use in the treatment of a gas stream containing an organometallic to prevent the deposition of metal within the pump, and examples of the metal include, but are not limited to, Al, Co, Cu, Fe, Hf, Ir, Ni, Mo, Nb, Ta, Ti, Va, Zn and Zr. Therefore, the present invention also provides a method of inhibiting the deposition of metal within a vacuum pump during the pumping from a process chamber of a gas stream containing an organometallic precursor, the method comprising the step of supplying a halogen to the gas stream upstream of the vacuum pump to react with the precursor to form a gaseous metallic halide. Examples of organometallic precursors which may react with a halogen to produce a gaseous halide include, but are not limited to, bis(N,N′-Diisopropylacetamidinato)cobalt(II), YBaCuOx Cu (N,N′-Di-sec-butylacetamidinato)copper(I), (N,N′-Diisopropylacetamidinato)copper(I), bis(N,N′-Di-tert-butylacetamidinato)iron(II), tetrakis(dimethylamido)hafnium, Ir(acac)₃, bis(N,N′-Diisopropylacetamidinato)nickel(II), molybdenum hexacarbonyl, niobium(V) ethoxide, tris(diethylamido)(tert-butylimido) tantalum(V), Bis(diethylamino)bis(diisopropylamino) titanium(IV), vanadyl tri-isopropoxide [VO(OiPr)₃], diethylzinc and tetrakis(diethylamido)zirconium(IV), in addition to the organoaluminium precursors mentioned above.

The present invention further provides apparatus for treating a gas stream containing an organometallic precursor prior to entering a vacuum pump, the apparatus comprising means for supplying a halogen to the gas stream upstream of the vacuum pump to react with the precursor to form a gaseous metallic halide.

Features described above in relation to the method aspects of the invention are equally applicable to the apparatus aspects, and vice versa.

The present invention will now be described, by way of example only, with reference to the accompanying drawing, which illustrates apparatus for treating a gas stream to prevent the deposition of metal within a vacuum pump. In this example, the apparatus is used to inhibit the deposition of aluminium within the pump, although as mentioned above the apparatus may be used to inhibit the deposition of another metal within the pump.

With reference to the drawing, a process chamber 10 for processing, for example, semiconductor devices, flat panel display devices or solar panel devices, receives various process gases for use in performing the processing within the chamber 10. These gases are conveyed to the chamber 10 from respective sources, indicated generally at 12 and 14 in the drawing although any number of sources may be provided. For example, sources of hydrogen and an organoaluminium precursor, for example one of trimethyl aluminium, triethyl aluminium, diethyl aluminium ethoxide, dimethyl aluminium hydride, triisobutyl aluminium, dimethyl ethyl amine alane, dimethyl aluminium isopropoxide, aluminium sec-butoxide, tris(dimethylamido) aluminium, tris(diethylamido) aluminium, tris(ethylmethylamido) aluminium, and an alkyl pyrroridine alane, such as methyl pyrroridine alane may be provided for the chemical vapour deposition of a layer of aluminium on a substrate located within the process chamber 10. The precursor may be conveyed to the process chamber 10 entrained within a carrier gas, for example one of argon and nitrogen.

A process tool 16 controls the supply of the process gases to the chamber 10 by supplying control signals to valves 18 and other flow control devices (not illustrated) for controlling the rate of supply of the process gases to the chamber 10.

A vacuum is generated within the process chamber 10 by a pumping system, which pumps an exhaust gas from the outlet of the chamber 10. During the processing within the chamber 10, only a portion of the process gases will be consumed, and so the exhaust gas will contain a mixture of the process gases supplied to the chamber 10, and by-products from the processing within the chamber 10. The pumping system may comprise a secondary pump 20, typically in the form of a turbomolecular pump or dry pump having intermeshing rotors, for drawing the exhaust gas from the chamber. A turbomolecular pump can generate a vacuum of at least 10⁻³ mbar in the chamber 10. Gas is typically exhausted from a turbomolecular pump at a pressure of around 1 mbar, and so the pumping systems also comprises a primary, or backing, pump 22 for receiving the gas exhaust from the secondary pump 20 and raising the pressure of the gas to a pressure around atmospheric pressure.

As discussed above, the presence of an organoaluminium precursor within the exhaust gas pumped from the chamber in combination with the elevated operating temperature within the secondary pump 20 can result in the unwanted deposition of aluminium within the secondary pump 20. In view of this, apparatus is provided for supplying a halogen, for example one of chlorine, bromine and iodine, to the foreline 24 extending between the process chamber 10 and the secondary pump 20 to react with the precursor to form a gaseous aluminium halide. In this example, chlorine is supplied to the foreline 24 to form aluminium chloride.

The chlorine is supplied to a reaction chamber 26 located within the foreline 24, between the process chamber 10 and the secondary pump 20. The chlorine is preferably supplied in the form of chlorine radicals (Cl*) or chlorine (Cl₂ and/or Cl). These species can be generated from, for example, CCl₄ supplied to a plasma generator 28, for example an MKS Astron AX7680 (MKS ASTex Products, Wilmington, Mass.) or similar device. Within the plasma generator 28, the CCl₄ reactant is conveyed through a plasma generated from an inert, ionisable gas, such as nitrogen or argon, which causes the reactant to thermally decompose. As the more reactive chlorine radicals will tend to recombine to form Cl₂ within a fairly short distance, the plasma generator 28 is preferably located proximate the reaction chamber 26 to maximise the likelihood of the chlorine radicals reaching the reaction chamber 26.

A controller 30 is provided for controlling the operation of the plasma generator 28. The controller 30 is preferably configured to control the plasma generator 28 so that chlorine is supplied to the reaction chamber 26 while the process tool is active, preferably just before the organoaluminium precursor is supplied to the process chamber 10, so that chlorine is present in the reaction chamber 26 when an exhaust gas containing the precursor is pumped from the process chamber 10. The controller 30 preferably receives signals from the process tool 16 indicative of the amount of precursor being supplied to the process chamber 10, in response to which the controller 30 can control the rate of supply of CCl₄ to the plasma generator 28, for example by controlling valve 32 located between the plasma generator and a CCl₄ source 34.

Within the reaction chamber, the chlorine reacts with the organoaluminium precursor to form AlCl₃, which can be pumped through the secondary pump 20 in gaseous form. Due to the reduction in the amount of organoaluminium precursor passing through the secondary pump 20, the amount of aluminium being deposited within the pump, due to the decomposition of the precursor therein, can be significantly decreased, thereby increasing the operating life of the pump.

As mentioned above, whilst in this example the apparatus is used to inhibit the deposition of aluminium within the pump, the apparatus may be used to inhibit the deposition of other metals within the pump. One or more of a number of organometallic precursors may be supplied to a process chamber for the deposition of a metal or compound on the surface of a substrate located in a process chamber, and these precursors may also be reacted with a halogen to produce a gaseous halide. Examples of these precursors include, but are not limited to, bis(N,N′-Diisopropylacetamidinato)cobalt(II), YBaCuOx Cu (N,N′-Di-sec-butylacetamidinato)copper(I), (N,N′-Diisopropylacetamidinato)copper(I), bis(N,N′-Di-tert-butylacetamidinato)iron(II), tetrakis(dimethylamido)hafnium, Ir(acac)₃, bis(N,N′-Diisopropylacetamidinato)nickel(II), molybdenum hexacarbonyl, niobium(V) ethoxide, tris(diethylamido)(tert-butylimido) tantalum(V), Bis(diethylamino)bis(diisopropylamino) titanium(IV), vanadyl tri-isopropoxide [VO(OiPr)₃], diethylzinc and tetrakis(diethylamido)zirconium(IV). The skilled person will no doubt be aware of other organometallic precursors which may be reacted with a halogen to produce a gaseous halide, and so the present invention is not to be restricted to aforementioned organometallic precursors or the metals contained therein.

1. A method of inhibiting the deposition of metal within a vacuum pump during the pumping from a process chamber of a gas stream containing an organometallic precursor, the method comprising the step of supplying a halogen to the gas stream upstream of the vacuum pump to react with the precursor to form a gaseous metallic halide.

2. The method according to claim 1 wherein the metal comprises at least one element selected from the group consisting of Al, Co, Cu, Fe, Hf, Ir, Ni, Mo, Nb, Ta, Ti, Va, Zn and Zr.

3. A method of inhibiting the deposition of aluminium within a vacuum pump during the pumping from a process chamber of a gas stream containing an organoaluminium precursor, the method comprising the step of supplying a halogen to the gas stream upstream of the vacuum pump to react with the precursor to form a gaseous aluminium halide.

4. The method according to claim 3 wherein the halogen comprises at least one component selected from the group consisting of chlorine, bromine and iodine.

5. The method according to claim 4 comprising the step of adding chlorine to the gas stream in the form of chlorine radicals.

6. The method according to claim 5 comprising the step of forming chlorine radicals by the thermal decomposition of a source of chlorine radicals.

7. The method according to claim 6 comprising the step of thermally decomposing the source of chlorine radicals by a plasma.

8. The method according to claim 6 wherein the source of chlorine radicals comprises CCl₄.

9. The method according to claim 3 comprising the step of conveying the halogen to a reaction chamber located between the process chamber and the pump.

10. The method according to claim 3 wherein the precursor is at least one compound selected from the group consisting of trimethyl aluminium, triethyl aluminium, diethyl aluminium ethoxide, dimethyl aluminium hydride, triisobutyl aluminium, dimethyl ethyl amine alane, dimethyl aluminium isopropoxide, aluminium sec-butoxide, tris(dimethylamido) aluminium, tris(diethylamido) aluminium, tris(ethylmethylamido) aluminium, and an alkyl pyrroridine alane, such as methylpyrroridine alane.

11. Apparatus for treating a gas stream containing an organometallic precursor prior to entering a vacuum pump, the apparatus comprising means for supplying a halogen to the gas stream upstream of the vacuum pump to react with the precursor to form a gaseous metallic halide.

12. Apparatus according to claim 11, wherein the supply means is arranged to supply at least one component selected from the group consisting of chlorine, bromine and iodine to the gas stream.

13. Apparatus according to claim 11 wherein the supply means is arranged to supply chlorine radicals to the gas stream, and comprises means for generating the chlorine radicals from a source thereof.

14. Apparatus according to claim 13 wherein the generating means is configured to thermally decompose the source of chlorine radicals.

15. Apparatus according to claim 14 wherein the generating means comprises a plasma generator.

16. Apparatus according to claim 11 comprising a reaction chamber for receiving the gas stream and the halogen from the supply means.

17. Apparatus according to claim 11 wherein the precursor comprises at least one compound selected from the group consisting of trimethyl aluminium, triethyl aluminium, diethyl aluminium ethoxide, dimethyl aluminium hydride, triisobutyl aluminium, dimethyl ethyl amine alane, dimethyl aluminium isopropoxide, aluminium sec-butoxide, tris(dimethylamido) aluminium, tris(diethylamido) aluminium, tris(ethylmethylamido) aluminium, and an alkyl pyrroridine alane, such as methylpyrroridine alane.

18. Apparatus for treating a gas stream containing an organoaluminium precursor prior to entering a vacuum pump, the apparatus comprising means for supplying chlorine to the gas stream upstream of the vacuum pump to react with the precursor to form aluminium chloride.

19. Apparatus for treating a gas stream containing an organometallic precursor prior to entering a vacuum pump, the apparatus comprising: a reaction chamber adapted to receive the gas stream and a halogen to react with the precursor to form a gaseous metallic halide upstream of the vacuum pump.

20. Apparatus for treating a gas stream containing an organoaluminium precursor prior to entering a vacuum pump, the apparatus comprising a reaction chamber adapted to receive the gas stream and chlorine to react with the precursor to form aluminium chloride upstream of the vacuum pump.
